(19) United States
(12) Patent Application Publication
(10) Pub. No.: US 2012/0268928 A1
(43) Pub. Date: Oct. 25, 2012

(54) LARGE SINGLE CHIP LED DEVICE FOR HIGH INTENSITY PACKING

(76) Inventor: Robert L. Sargent, CHELMSFORD, MA (US)

(21) Appl. No.: 13/280,493

(22) Filed: Oct. 25, 2011

Related U.S. Application Data
(60) Provisional application No. 61/406,691, filed on Oct. 26, 2010.

(51) Int. Cl. F21V 9/00; H05K 13/04; F21V 21/00

(52) U.S. Cl. 362/231; 362/249.02; 29/832

(57) ABSTRACT

A LED chip device comprises an electrically conductive base overlain by a dielectric layer. A recess in the dielectric exposes the base. A LED is mounted on the base in the recess such that the LED is substantially flush with a side of the base. The LED is electrically connected to pads disposed on the dielectric layer on opposing sides of the LED and the pads are electrically connected to each other.

### CROSS-REFERENCES TO RELATED APPLICATIONS

This application claims priority under 35 U.S.C. §119 (e) to, and hereby incorporates by reference, U.S. Provisional Application No. 61/406,691 filed 26 Oct. 2010.

### BACKGROUND OF THE INVENTION

1. Field of the Invention

This invention relates to LED deployment and, in particular, this invention relates to configurations of LED devices for high density packing.

2. Background

LEDs are usually mounted on the surface of devices which provide electricity to the LED and often provide a means of conveying heat away from the LED during operation. These LED devices have previously had considerably greater surface area than the surface area of the mounted LEDs because of the need for space to accommodate electrical connection, provide electrical current, and to provide for mechanisms to convey heat away from the LED. However, LEDs are often deployed in pluralities because of the larger surface areas of objects to be illuminated. Moreover, single LEDs have the limitation of a single peak wavelength of illumination. When pluralities of LED devices of the prior art are deployed together, the rather large distances between the illuminated LEDs creates often unacceptable variations in illumination intensity.

There is then a need for an LED device that can be operably deployed to achieve a higher fill factor of illumination. There is a particular need for an LED device which can be operably deployed by being lined up side by side in closer proximity than previously possible.

### SUMMARY OF THE INVENTION

This invention substantially meets the aforementioned needs of the industry by providing an LED device that can be operably deployed to achieve a higher fill factor of illumination by being lined up side by side and in closer proximity than previously possible.

Accordingly there is provided a LED carrier, the LED carrier including an electrically conductive base with first and second base sides; a dielectric layer disposed over a surface of said base, a recessed area extending through said dielectric layer exposing said base; a pair of electrically conductive contact pads disposed over said dielectric layer, one of said contact pads electrically connected to the other of said contact pads; a LED (light emitting diode) disposed within said recessed area and contacting said base, one edge of said LED substantially flush with said first side of said base; and a plurality of electrical connections connecting said LED to each of said contact pads.

There is also provided a method of emitting electromagnetic radiation from an LED, said LED including an electrically conductive base with first and second base sides; a dielectric layer disposed over a surface of said base, a recessed area extending through said dielectric layer exposing said base; a pair of electrically conductive contact pads disposed over said dielectric layer, one of said contact pads electrically connected to the other of said contact pads; a LED disposed within said recessed area and contacting said base, one edge of said LED substantially flush with said first side of said base; and a plurality of electrical connections connecting said LED to each of said contact pads; said method including passing an electric current through said LED.

There is yet provided a method of manufacturing a LED carrier, including, contacting an LED to an electrically conductive base at a recess a dielectric layer overlaying said base such that said LED is substantially flush with a first edge of said base; and connecting bonds between said LED and a wire pad and between said LED and a contact pad, wherein said wire pad and said contact pad are electrically connected.

The present LED carrier may also include a contact electrically connected to the base, the dielectric layer interposed between the contact and the base.

The base may include copper, which may be gold plated. The contact pads may be electrically connected by a trace proximate the base second side.

A plurality of the present LED carriers may be utilized, electrically connected in parallel or series and a plurality of peak wave lengths of electromagnetic radiation may be operably emitted by the plurality of LEDs.

### BRIEF DESCRIPTION OF THE DRAWINGS

FIG. 1 is a perspective view of one embodiment of a LED carrier of this invention.

FIG. 2 is a plan view of the LED carrier of FIG. 1.

FIG. 3 is a plan view of three LED carriers shown in FIGS. 1 and 3 deployed side by side.

It is understood that the above-described figures are only illustrative of the present invention and are not contemplated to limit the scope thereof.

### DETAILED DESCRIPTION

Any references to such relative terms as front and back, right and left, top and bottom, upper and lower, horizontal and vertical, or the like, are intended for convenience of description and are not intended to limit the present invention or its components to any one positional or spatial orientation. All dimensions of the components in the attached figures may vary with a potential design and the intended use of an embodiment of the invention without departing from the scope of the invention.

Each of the additional features and methods disclosed herein may be utilized separately or in conjunction with other features and methods to provide improved devices of this invention and methods for making and using the same. Representative examples of the teachings of the present invention, which examples utilize many of these additional features and methods in conjunction, will now be described in detail with reference to the drawings. This detailed description is merely intended to teach a person of skill in the art further details for practicing preferred aspects of the present teachings and is not intended to limit the scope of the invention. Therefore, combinations of features and methods disclosed in the following detailed description may not be necessary to practice the invention in the broadest sense, and are instead taught merely to particularly describe representative and preferred embodiments of the invention.

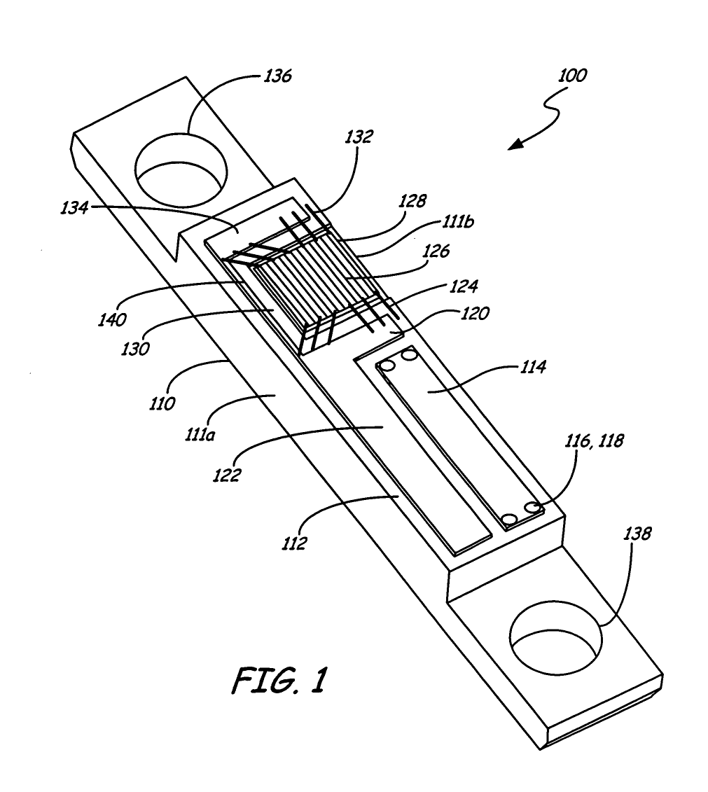

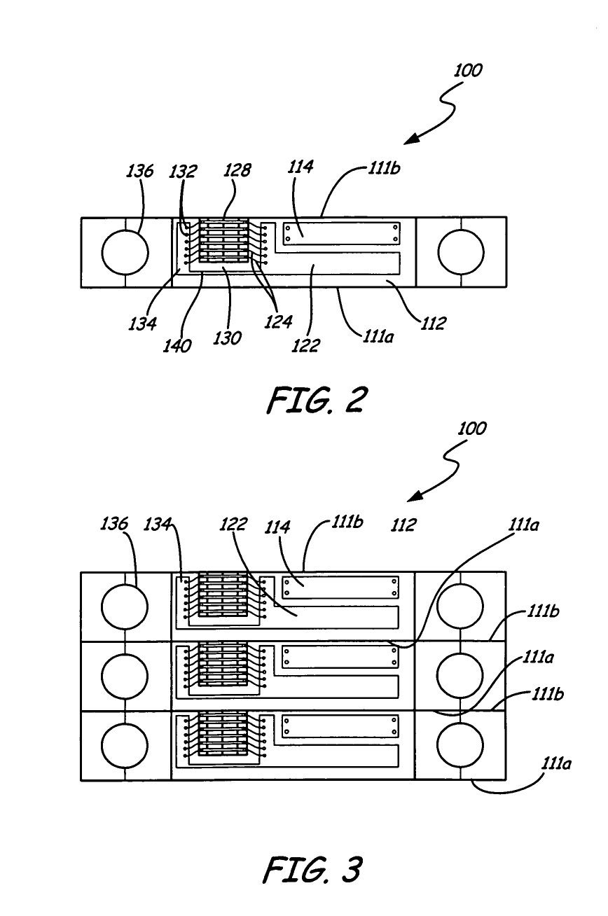

FIGS. 1, 2, 3 show a LED carrier or LED package 100 of this invention. As shown, a copper base 110 is formed by a machining process known to the art to a form with opposing (e.g., first and second longitudinal) sides 111a, 111b. Once formed, the copper base 110 is gold plated with a dielectric layer 112 disposed atop the base 110 as an electrical insulative layer. A contact 114 is present on the dielectric layer 112, the contact accessing the copper base material by means of four holes 116. Electrically conductive connectors, such as copper rivets 118 or the like, are present in these holes to complete the electrical communication between the contact and the copper base material. On the left side 120 of a LED contact pad 122 is an electrical communication 124 to the top surface 126 of a LED (light emitting diode) 128. The base 110, contact pad 114, and LED 128 are dimensioned and configured such that the LED 128 is mounted in a recessed area 130 allowing direct contact of the LED 128 to the copper base material 110. The LED 128 is then wire-bonded 132 from the top side of the LED 128 down to the left hand contact pad 134. In the embodiment shown, the leads or bonds 124 are continuous with the leads or bonds 132 and are substantially evenly spaced over the surface of, and contacting, the LED 128.

As described herein the LED carrier 100 of this invention may, without limitation, be utilized in an application requiring a tight line focus by allowing the LEDs present thereon to be essentially lined up side-by-side to attain a maximum fill factor along the line of LEDs. Accordingly, a maximum amount of light (radiation) or optimum power can be attained along a focus line.

Utilizing the LED carrier or package of this invention, one can alternate LEDs having differing or mixed wavelengths (peak wavelengths). For example, LEDs having peak wavelengths of 385 nm and 365 nm can be alternated and the alternate peak wavelength LEDs then disposed along a uniform line to produce two peak wavelengths uniformly or otherwise dispersed when such is desired. One or a plurality of the LED packages of this invention may be fixed into place, for example, by securing connectors through mounting holes 136, 138. FIG. 3 shows three LED packages 100 deployed side by side such that edge 111b of the middle LED package is proximate or contacting edge 111b of the upper LED package and such that edge 111a of the middle LED package is proximate or contacting edge 111b of the lower LED package. However, the middle LED carrier of FIG. 3 could be inverted so that the side 111b thereof is adjacent the side 111b of the lower LED carrier to thereby achieve a still greater packing density if desired.

As can be seen in FIG. 3, the LED carrier or package of this invention allows for a minimum package width having a trace 140 extending along one side thereof allowing wire bonding to the other side of a die, thereby enhancing the current-spreading capability on the top surface of the die. Such current-spreading is important in powering LEDs to attain uniform irradiation output.

The LED carrier or package of this invention is designed for a single LED per device, with a large copper base well adapted for thermal conductivity and a flat bottom, also optimally configured for thermal conductivity. The bottom of the copper base of this invention optimally interfaces with a cooling plate, the cooling plate either air-cooled or water-cooled. Accordingly, the direct contact between the bottom of the LED and gold-plated copper effects the best possible conductivity into the LED package thermally, as opposed to other packages with the LED disposed atop dielectric material. When the LED is disposed atop dielectric material, thermal performance is less than ideal.

The LED carrier or package of this invention is designed to:
1. achieve a tight focal line concentration of LEDs with a plurality of the devices;
2. be used with optics where fill-factor along the focal line is a priority; and
3. attain blended wavelengths as described herein.

The LED carrier or package of this invention includes an offset die-mount, in which one side of the LED die is flush with one side of the chip, so that a trace can be routed to the other side of the chip minimizing the width of the device in relation to the LED die size, for example, 3 mm×3 mm.

The LED carrier or package of this invention includes a flat copper-slug design for easy service mounting onto a flat-cooled interface.

Other known LED carriers or packages of the prior art involve mounting the die at the middle of the package, thereby leaving material on both sides of the die and thereby creating stack-up and sacrificing pitch (distancing or fill factor) of the LEDs when arranged in series.

It should be understood that the LED carrier or package of this invention may include mounting multiple dies on a single device. The separate LED dies may then be electrically driven in parallel or may be electrically driven in series with the addition of a suitably designed electrically isolative layer and conductive traces. However, depending the thermal performance of the dielectric layer, the thermal performance of the series design may be comprised at high drive current.

It should be further understood that this description and accompanying illustrations are not limiting, but are merely illustrative, of one embodiment of this invention. Accordingly, the metes and bounds of this invention are determined by the claims present hereinbelow.

What is claimed is:

1. An LED carrier, comprising:
an electrically conductive base with first and second base sides;
a dielectric layer disposed over a surface of said base, a recessed area extending through said dielectric layer exposing said base;
a pair of electrically conductive contact pads disposed over said dielectric layer, one of said contact pads electrically connected to the other of said contact pads;
a LED (light emitting diode) disposed within said recessed area and contacting said base, one edge of said LED substantially flush with said first side of said base; and
a plurality of electrical connections connecting said LED to each of said contact pads.

2. The LED carrier of claim 1, further comprising a contact, said dielectric layer disposed between said contact and said base, said contact electrically connected to said base.

3. The LED carrier of claim 2, further comprising a plurality of rivets electrically connecting said contact to said base.

4. The LED carrier of claim 1, wherein said electrical connections connect a top surface of said LED to each of said contact pads.

5. The LED carrier of claim 1, wherein said base comprises copper.

6. The LED carrier of claim 5, wherein said copper base is gold plated.

7. The LED carrier of claim 1, wherein said contact pads are electrically connected by a trace, said trace proximate said base second side.

8. A plurality of LED carriers of claim 1, wherein said LEDs emit differing peak wavelengths.

9. The plurality of LED carriers of claim 8, wherein one of said LEDs emits a peak wavelength of about 385 nm and one of said LEDs emits a peak wavelength of about 365 nm.

10. The plurality of LED carriers of claim 8, wherein said LEDs are electrically connected in a series.

11. The plurality of LED carriers of claim 8, wherein said LEDs are electrically connected in parallel.

12. A method of emitting electromagnetic radiation from an LED (light emitting diode), said LED comprising an electrically conductive base with first and second base sides; a dielectric layer disposed over a surface of said base, a recessed area extending through said dielectric layer exposing said base; a pair of electrically conductive contact pads disposed over said dielectric layer, one of said contact pads electrically connected to the other of said contact pads; a LED disposed within said recessed area and contacting said base, one edge of said LED substantially flush with said first side of said base; and a plurality of electrical connections connecting said LED to each of said contact pads;
said method comprising passing an electric current through said LED.

13. The method of claim 12, wherein said electric current is passed through a pair of LEDs.

14. The method of claim 13, wherein each of said pair of LEDs emits a different peak wavelength radiation.

15. The method of claim 12, wherein said LEDs are electrically connected in a series.

16. The method of claim 12, wherein said LEDs are electrically connected in parallel.

17. A method of manufacturing a LED carrier, comprising,
contacting an LED (light emitting diode) to an electrically conductive base at a recess a dielectric layer overlaying said base such that said LED is substantially flush with a first edge of said base; and
connecting bonds between said LED and a wire pad and between said LED and a contact pad, wherein said wire pad and said contact pad are electrically connected.

18. The method of claim 17, wherein said wire pad and said contact pad are electrically connected by a trace, said trace extending proximate a second side of said base, said second side opposite said first side.

19. The method of claim 17, further comprising electrically connecting a pad to said base, wherein said dielectric layer is disposed between said pad and said base.

20. The method of claim 19, wherein said pad and said base are electrically connected by rivets.
